(19) United States
(12) Patent Application Publication
(10) Pub. No.: US 2025/0279400 A1
(43) Pub. Date: Sep. 4, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hitoshi IMI, Yokohama Kanagawa (JP); Yutaka HORIE, Mitaka Tokyo (JP); Shugo SUZUKI, Hanno Saitama (JP); Yasutomo SAKURAI, Kawasaki Kanagawa (JP); Masahiro KOYAMA, Machida Tokyo (JP)

(21) Appl. No.: 19/048,763

(22) Filed: Feb. 7, 2025

(30) Foreign Application Priority Data
Mar. 4, 2024 (JP) 2024-032212

(51) Int. Cl. H01L 25/07; H01L 23/00; H01L 23/495

(52) U.S. Cl. CPC H01L 25/072; H01L 23/49562; H01L 24/32; H01L 24/48; H01L 24/73; H01L 24/49; H01L 2224/32245; H01L 2224/48091; H01L 2224/4814; H01L 2224/48245; H01L 2224/49175; H01L 2224/73265; H01L 2924/1033; H01L 2924/13064; H01L 2924/13091

(57) ABSTRACT

According to one embodiment, a semiconductor device has a first terminal, and a second terminal in which a first groove portion is formed through an upper face thereof. Also, the semiconductor device has a first transistor that has a first drain electrode electrically connected to the first terminal, a first source electrode, and a nitride semiconductor layer, and is provided in the first groove portion. Further still, the semiconductor device includes a second transistor that has a second drain electrode electrically connected to the second terminal and a second source electrode electrically connected to the first source electrode.

### CROSS-REFERENCE TO RELATED APPLICATION(S)

This application is based upon and claims the benefit of priority from Japanese Patent Application No. 2024-032212, filed Mar. 4, 2024, the entire contents of which are incorporated herein by reference.

### FIELD

Embodiments described herein relate generally to a semiconductor device.

### BACKGROUND

A power semiconductor including a gallium-nitride (GaN) transistor in which GaN is used is already known. A GaN transistor enables high speed switching, and is used in a power conversion device. As this kind of power semiconductor is subject to a large amount of electric power, heat dissipation measures are important.

### BRIEF DESCRIPTION OF THE DRAWINGS

FIG. 1 is one example of a block diagram of a semiconductor device according to a first embodiment.

FIG. 2 is one example of a circuit diagram of the semiconductor device according to the first embodiment.

FIG. 3 is a plan view of the semiconductor device according to the first embodiment.

FIG. 4 is a schematic sectional view representing a cross-section of the semiconductor device taken along line A-A shown in FIG. 3.

FIG. 5 is one example of a heat dissipating structure of the semiconductor device according to the first embodiment.

FIG. 6 is a plan view of a semiconductor device according to a second embodiment.

FIG. 7 is a schematic sectional view representing a cross-section of the semiconductor device taken along line B-B shown in FIG. 6.

### DETAILED DESCRIPTION

Embodiments provide a semiconductor device such that a heat dissipation performance is improved.

In general, according to one embodiment, a semiconductor device has a first terminal, and a second terminal in which a first groove portion is formed through an upper face thereof. Also, the semiconductor device has a first transistor that has a first drain electrode electrically connected to the first terminal, a first source electrode, and a nitride semiconductor layer, and is provided in the first groove portion. Furthermore, the semiconductor device includes a second transistor that has a second drain electrode electrically connected to the second terminal and a second source electrode electrically connected to the first source electrode.

Hereafter, embodiments of the present disclosure will be described, with reference to the drawings. In the description, identical reference signs will be assigned to identical portions in all the drawings.

The present disclosure is not limited by the embodiments, and dimensional ratios of the drawings are not limited to the ratios shown in the drawings.

### First Embodiment

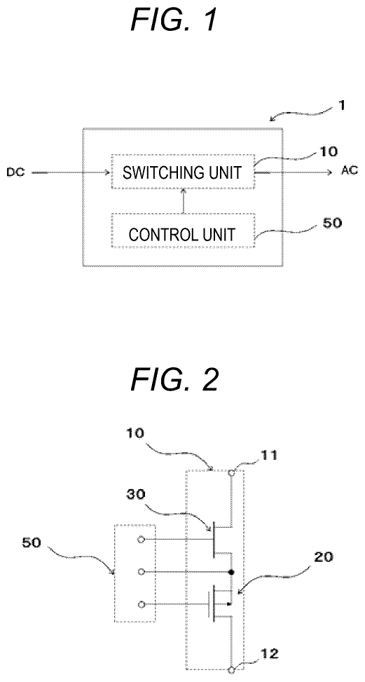

FIG. 1 is a block diagram showing a configuration of a semiconductor device 1 according to a first embodiment. A semiconductor device according to the first embodiment is a power semiconductor, which can be used in a power conversion device such as an inverter or a converter.

The semiconductor device 1 includes a configuration such that a plurality of semiconductor chips are collected in one package. As shown in FIG. 1, the semiconductor device 1 includes a switching unit 10 and a control unit 50. By carrying out switching, the switching unit 10, for example, converts an input direct current (DC) power supply into an alternating current (AC) signal, and outputs the signal. The control unit 50 controls a switching operation by the switching unit 10.

Next, referring to FIG. 2, a circuit configuration of a semiconductor device according to the embodiment will be described.

FIG. 2 is a circuit diagram showing one example of a circuit configuration of a semiconductor device according to the embodiment. As shown in FIG. 2, the semiconductor device 1 has a first terminal 11, a second terminal 12, a gallium-nitride (GaN) transistor 30, and a MOS transistor 20. The GaN transistor 30 and the MOS transistor 20 are cascode-connected between the first terminal 11 and the second terminal 12. The GaN transistor 30 is one example of a first transistor. Also, the MOS transistor 20 is one example of a second transistor.

The GaN transistor 30 includes a normally-on high electron mobility transistor (HEMT) that is in an on-state when, for example, no signal is input into its gate. That is, when a difference in potential between its gate and its source is 0V, its drain end and its source end are electrically connected.

The MOS transistor 20 is a metal-oxide-semiconductor field-effect transistor (MOSFET) in which, for example, silicon is used. The MOS transistor 20 according to the first embodiment has normally-off characteristics, and is a p-type MOSFET. That is, when a difference in potential between its gate and its source is 0V, its drain end and its source end are electrically isolated.

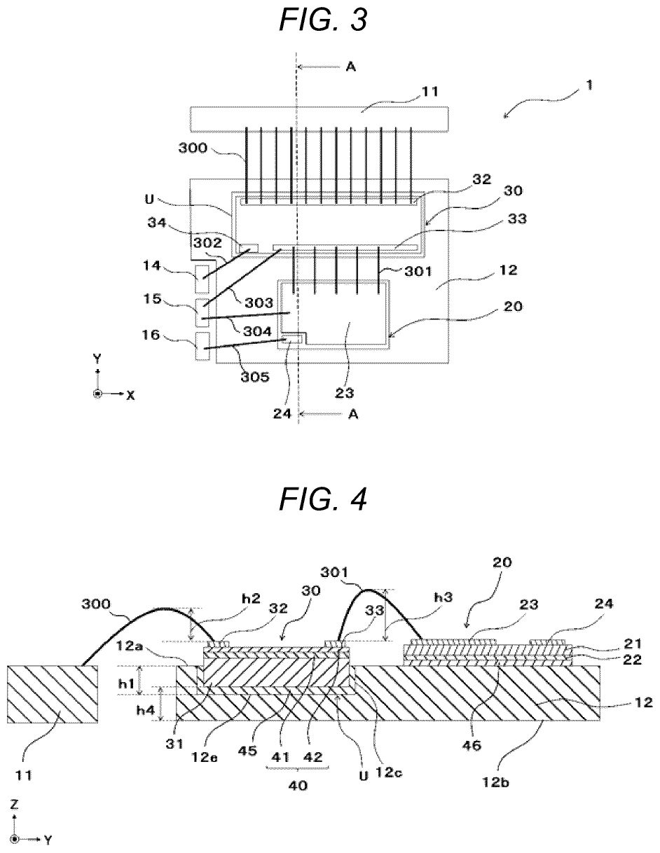

Next, an internal structure of the semiconductor device 1 according to the first embodiment will be described, using FIGS. 3 and 4.

FIG. 3 is a top view showing one example of an internal structure of the semiconductor device 1 according to the first embodiment, and FIG. 4 is a schematic sectional view representing a cross-section of the semiconductor device taken along line A-A shown in FIG. 3. The control unit 50 is omitted.

According to FIG. 3, the GaN transistor 30 and the MOS transistor 20 are provided on the second terminal 12, and the first terminal 11, a GaN gate terminal 14, a source control terminal 15, and a MOS gate terminal 16 are provided in the same plane as the second terminal 12. Herein, the source control terminal 15 determines, for example, a reference potential of voltage applied by the GaN gate terminal 14 and the MOS gate terminal 16. The GaN gate terminal 14 is one example of a first gate terminal, and the MOS gate terminal 16 is one example of a second gate terminal.

A lead frame that is made of metal is used to form the first terminal 11, the second terminal 12, the GaN gate terminal 14, the source control terminal 15, and the MOS gate terminal 16.

Herein, a plane in which the lead frame is disposed is an XY plane, and a direction that intersects the XY plane and extends from bottom faces toward upper faces of the GaN transistor 30 and the MOS transistor 20 is a +Z direction or an upward direction.

In the lead frame disposed in the XY plane, a direction extends from the second terminal 12 toward the first terminal 11 is a +Y direction. The first terminal 11 is disposed, for example, separated from the second terminal 12 in such a way that end portions are opposed in the Y direction. At this time, the GaN gate terminal 14, the source control terminal 15, and the MOS gate terminal 16 are disposed in parallel in the Y direction.

Further still, there are X directions perpendicular to the Y direction. A direction extending from the GaN gate terminal 14, the source control terminal 15, and the MOS gate terminal 16 toward the second terminal 12 is a +X direction. The GaN gate terminal 14, the source control terminal 15, and the MOS gate terminal 16 are disposed, for example, separated from the second terminal 12 in such a way that end portions are opposed in the X direction.

Herein, a connection relationship of each terminal will be described.

Firstly, the GaN gate terminal 14, the source control terminal 15, and the MOS gate terminal 16 are, for example, connected to the control unit 50, which is a gate driver circuit or the like.

Also, the GaN gate terminal 14 is connected to the GaN transistor 30, and the source control terminal 15 is connected to both the GaN transistor 30 and the MOS transistor 20. Further, the MOS gate terminal 16 is connected to the MOS transistor 20.

Further still, the GaN transistor 30 and the MOS transistor 20 are electrically connected. Current is caused to flow from the first terminal 11 to the second terminal 12 via the GaN transistor 30 and the MOS transistor 20 based on a control by the GaN gate terminal 14, the source control terminal 15, and the MOS gate terminal 16.

Next, a configuration of a GaN transistor will be described.

As shown in FIG. 4, the GaN transistor 30 has a first drain electrode 32, a first source electrode 33, a substrate 31, and a first semiconductor layer 40 provided on the substrate 31.

The substrate 31 is, for example, a silicon substrate. A resistance of the substrate 31 is, for example, 1 mΩ/cm or greater, 1 Ω/cm or less.

The first semiconductor layer 40 that is of, for example, a two-layer structure, has a heterojunction structure including a first nitride semiconductor layer 41 and a second nitride semiconductor layer 42. The first nitride semiconductor layer 41 is provided on the substrate 31, and the second nitride semiconductor layer 42 is provided on the first nitride semiconductor layer 41. The second nitride semiconductor layer 42 has a bandgap greater than that of the first nitride semiconductor layer 41. For example, the first nitride semiconductor layer 41 is, for example, an undoped GaN layer, and the second nitride semiconductor layer 42 is an AlGaN layer. A two-dimensional electron gas is formed in a vicinity of an interface of the first nitride semiconductor layer 41 with the second nitride semiconductor layer 42.

The first semiconductor layer 40 is, for example, 5 μm or less, and the substrate 31 has a thickness of about 200 μm.

A first drain electrode 32 and a first source electrode 33 are provided on the first semiconductor layer 40. The first drain electrode 32 and the first source electrode 33 are in contact with the second nitride semiconductor layer 42. A first gate electrode 34 shown in FIG. 3 is provided on an insulating film (not shown) in a region that is on the second nitride semiconductor layer 42. The first gate electrode 34 in FIG. 3 may extend into the region between the first drain electrode 32 and the first source electrode 33.

As shown in FIG. 3, the GaN gate terminal 14 is connected to the first gate electrode 34 of the GaN transistor 30, and controls a drive of the GaN transistor 30 in accordance with a magnitude of a gate voltage applied thereto.

The first drain electrode 32 of the GaN transistor 30 is electrically connected to the first terminal 11 by a plurality of first wires 300.

The first source electrode 33 of the GaN transistor 30 is electrically connected to a second source electrode 23 by a plurality of second wires 301.

The GaN gate terminal 14 and the first gate electrode 34 of the GaN transistor 30 are also electrically connected by a third wire 302.

The first source electrode 33 of the GaN transistor 30 and the source control terminal 15 are also electrically connected by a fourth wire 303.

Wire includes bonding wire formed of, for example, conductive wire.

As shown in FIGS. 3 and 4, the GaN transistor 30 is provided on a joining material 45 such as a resin in a groove portion U formed through an upper face 12a of the second terminal 12. The groove portion U is one example of a first groove portion. The joining material 45 is one example of a first joining material.

A conductive material such as a solder may also be used as the joining material 45.

The groove portion U has a size equivalent to, or greater than, that of the GaN transistor 30 in order that the entirety of the GaN transistor 30 can be housed therein.

Herein, a height hl from a bottom face 12e of the groove portion U to an upper face 12a of the second terminal 12 represents a depth of the groove portion U. In the present embodiment, the height hl is formed to be smaller than a thickness of the substrate 31 of the GaN transistor 30.

That is, a bottom face of the first semiconductor layer 40 is disposed above the upper face 12a of the second terminal 12. For example, when a thickness of the second terminal 12 is 500 μm and the thickness of the substrate 31 of the GaN transistor 30 is 200 μm, the height h1 of the groove portion U is less than 200 μm.

The joining material 45 may be applied in such a way so as to cover a bottom face and side faces of the substrate 31 of the GaN transistor 30.

Also, the distance from bottom face 12e of groove portion U to upper face 12a of second terminal 12 in the thickness direction of the second terminal 12 is smaller than the thickness of the portion of the substrate 31. This allows the first semiconductor layer 40 and the joining material 45 to be separated. When the joining material 45 is a conductive material such as a solder, risk of the first semiconductor layer 40 and the second terminal 12 being electrically short-circuited is reduced.

The groove portion U may be formed by a pressing process or the like, in which a molding die is used, or by an etching process or the like, in which metal corrosion is employed.

Next, a configuration of the MOS transistor 20 will be described.

As shown in FIG. 4, the MOS transistor 20 is mounted on the second terminal 12, and has a second semiconductor layer 21 and a second drain electrode 22 provided on a bottom face of the second semiconductor layer 21. The second drain electrode 22 is joined to the second terminal 12 by a conductive joining material 46 such as a solder. The joining material 46 is one example of a second joining material. The second drain electrode 22 is electrically connected to the second terminal 12. The MOS transistor 20 has the second source electrode 23 and a second gate electrode 24 on another face opposing the second drain electrode 22 in a thickness direction of the second semiconductor layer 21. The second semiconductor layer 21 is, for example, a silicon layer, and includes a p-type channel. The MOS transistor 20 is a vertical device in which current flows in the thickness direction of the second semiconductor layer 21 (a vertical direction linking the second drain electrode 22 and the second source electrode 23). The channel of the MOS transistor 20 formed in the second semiconductor layer 21 may be formed in the horizontal direction or in the depth direction.

As shown in FIG. 3, the second source electrode 23 of the MOS transistor 20 and the source control terminal 15 are electrically connected by a fifth wire 304. The second gate electrode 24 of the MOS transistor 20 and the MOS gate terminal 16 are electrically connected by a sixth wire 305. The MOS gate terminal 16 controls a drive of the MOS transistor 20 in accordance with a magnitude of a gate voltage applied thereto.

The first source electrode 33 of the GaN transistor 30 is electrically connected to the second source electrode 23. Further, the first source electrode 33 of the GaN transistor 30 is electrically connected to the second terminal 12 via the MOS transistor 20.

In the present embodiment, the GaN transistor 30 is housed in the groove portion U of the second terminal 12. As a result, heights in the Z direction of the first drain electrode 32, the first source electrode 33, and the first gate electrode 34 are lowered. In this embodiment, a thickness of the first drain electrode 32 and a thickness of the first source electrode 33 are substantially the same.

In this embodiment, as shown in FIG. 4, an arched height h2 of the first wire 300 connecting the first drain electrode 32 and the first terminal 11 may be lower than an arched height h3 of the second wire 301 connecting the first source electrode 33 and the second source electrode 23. A lower arched height, which is determined by a distance between a wire starting point and a wire ending point and by a difference in heights thereof, is advantageous in reducing a part size. The arched height h2 is the vertical distance between the uppermost position where the first wire 300 bends and the first source electrode 32. The arched height h3 is the vertical distance between the uppermost position where the second wire 301 bends and the first source electrode 33. In this embodiment, the uppermost position of first wire 300 is below the uppermost position of second wire 301.

The semiconductor device 1 configuring the heretofore described internal structure has a structure sealed by a sealing resin (not shown).

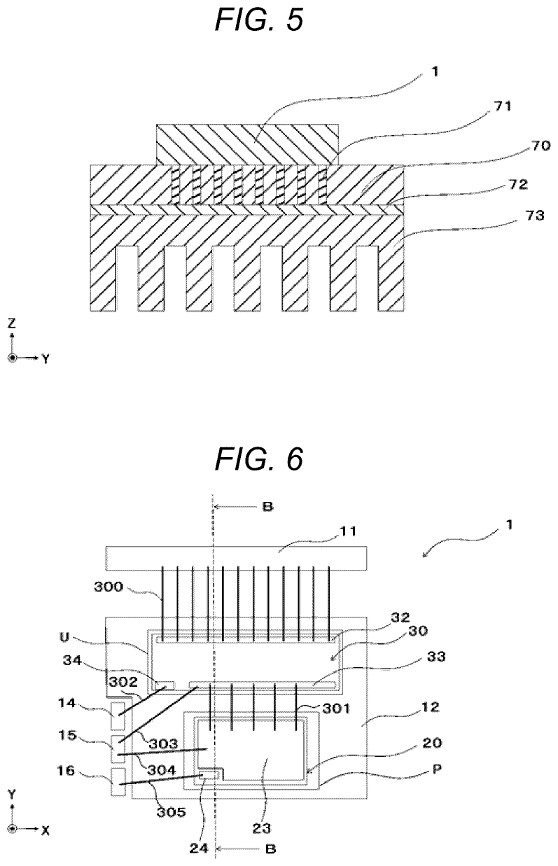

Next, a heat dissipating structure of the semiconductor device 1 according to the present embodiment will be described, using FIG. 5.

FIG. 5 is a schematic sectional view showing a heat dissipating structure of the semiconductor device 1. The GaN transistor 30 is mounted in the semiconductor device 1. As the GaN transistor 30 is subject to a large amount of electric power, cooling measures with respect to heat generation are important. A main substrate 70 on which the semiconductor device 1 is mounted is bonded to a heat sink 73 across an intermediate material 72 such as a thermal interface material (TIM).

A heat dissipating via 71 is provided in the main substrate 70 to extend from the front side thereof to the back side thereof, causing heat from the semiconductor device 1 to be transferred to the heat sink 73.

A semiconductor device cooling method, not being limited to the present example, may be a method that employs air cooling or water cooling using a fin or a heat pipe.

In the case of the kind of cooling method of FIG. 5, a heat dissipation path of heat generated from the semiconductor device 1 is such that heat is transferred from a bottom face of the semiconductor device 1 through the heat dissipating via 71, the intermediate material 72, and the heat sink 73, in this order, and then finally discharged by the heat sink 73. That is, heat generated in the GaN transistor 30 is discharged along the heretofore described heat dissipation path via a main face 12b of the second terminal 12 that is exposed on the bottom face of the semiconductor device 1.

According to the semiconductor device 1 of the present embodiment, the groove portion U for housing the GaN transistor 30 is formed in a region of the second terminal 12.

Because of the groove portion U, heat is transferred to the main face 12b from not only the bottom face 12e in the groove portion U, but also from a side face 12c. Because of this, a semiconductor device that is highly reliable in terms of heat dissipation performance and electrical characteristics can be obtained. The side face 12c is perpendicular to the bottom face 12e of the groove portion U in a peripheral edge portion of the bottom face 12e.

Furthermore, because the distance h4 from a bottom face of the GaN transistor 30 to the main face 12b is less than the thickness of the second terminal 12, thermal resistance can be reduced in comparison with a structure in which the groove portion U is not provided.

Also, a semiconductor device in which the GaN transistor 30 is used, as is the case with the semiconductor device 1 according to the present embodiment, has high-speed switching properties. As a result, the effect of parasitic inductance thereon is considerable.

Because the GaN transistor 30 is housed in the groove portion U, as is the case with the semiconductor device 1 according to the present embodiment, a height in the Z direction of the first drain electrode 32 of the GaN transistor 30 is lowered. Because of this, the arched height h2 of the first wire 300 connecting the first drain electrode 32 and the first terminal 11 is low. As a result, a wire length between the first drain electrode 32 and the first terminal 11 is short, meaning that an advantage is obtained in that parasitic inductance of the wire is reduced.

Because the GaN transistor 30 is housed in the groove portion U provided in the second terminal 12, heat dissipation performance and electrical characteristics can be improved.

Further still, because the groove portion U is provided, positional deviation when the GaN transistor 30 is mounted can be prevented, and spreading of the joining material 45 can be restricted. Because of this, distance between parts can be reduced, meaning that a reduction in part size and high-density mounting can be achieved.

### Second Embodiment

Next, a second embodiment will be described. As shown in FIG. 6, the second embodiment differs from the first embodiment in that a groove portion P that houses the MOS transistor 20 is further provided. The groove portion P is one example of a second groove portion. Other than the groove portion P and the MOS transistor 20 being provided in the groove portion P, the semiconductor device 1 of the second embodiment has the same configurations as the configurations of the semiconductor device 1 of the first embodiment. In the same way as the groove portion U in which the GaN transistor 30 is housed, the groove portion P is of a size equivalent to or greater than that of the MOS transistor 20. When the MOS transistor 20 is in an on-state, current flows in a transistor thickness direction. In the present embodiment, for example, the groove portion P is formed to have a depth greater than a height of the MOS transistor 20, and a structure such that a side face 12d of the groove portion P and a side face of the MOS transistor 20 are separated is adopted. The side face 12d is perpendicular to a bottom face 12f of the groove portion P in a peripheral edge portion of the bottom face 12f.

Also, a structure such that the MOS transistor 20 is provided on the bottom face 12f of the groove portion P across the joining material 46 is adopted. In this case, the joining material 46 is separated from (without contacting) at least the side face 12d. Because of this, risk of the MOS transistor 20 and the second terminal 12 being electrically short-circuited across the joining material 46 can be reduced.

A semiconductor device according to the present embodiment is such that the groove portion U for housing the GaN transistor 30 and the groove portion P for housing the MOS transistor 20 are each provided in the second terminal 12. Because of this, heat dissipation performance and electrical characteristics of both the GaN transistor 30 and the MOS transistor 20 can be improved, and a semiconductor device that is even more highly reliable than that in the first embodiment can be obtained.

Because the MOS transistor 20 is housed in the groove portion P, a heat dissipation path in a thickness direction of the second terminal 12 can be shortened, and thermal resistance can be reduced.

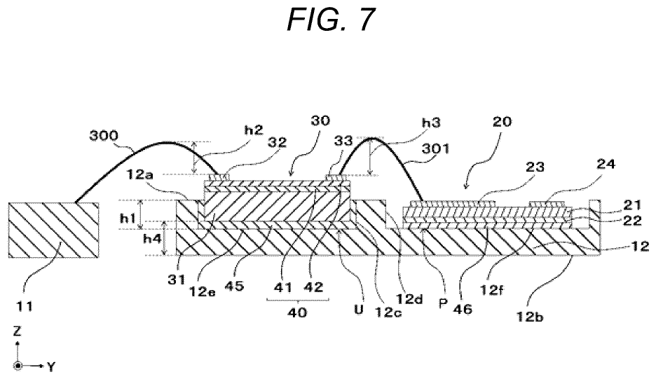

Also, as shown in FIG. 7, the arched height h3 of the second wire 301 between the second source electrode 23 of the MOS transistor 20 and the first source electrode 33 of the GaN transistor 30 is lowered. Because of this, a wire length between the second source electrode 23 and the first source electrode 33 is reduced, whereby parasitic inductance of the wire can be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first terminal;
a second terminal having a first groove portion formed through an upper face thereof;
a first transistor provided in the first groove portion, the first transistor having a first drain electrode electrically connected to the first terminal, a first source electrode, and a nitride semiconductor layer;
a second transistor having a second drain electrode electrically connected to the second terminal and a second source electrode electrically connected to the first source electrode.

2. The semiconductor device according to claim 1, wherein the first transistor is a normally-on, gallium-nitride, high electron mobility transistor (HEMT), and the second transistor is a normally-off metal-oxide-semiconductor field-effect transistor (MOSFET).

3. The semiconductor device according to claim 1, wherein a first gate terminal of the first transistor, a second gate terminal of the second transistor, and a source control terminal are further provided, and the source control terminal is electrically connected to the first source electrode and the second source electrode.

4. The semiconductor device according to claim 3, wherein the first gate terminal is electrically connected to a first gate electrode of the first transistor, and the second gate terminal is electrically connected to a second gate electrode of the second transistor.

5. The semiconductor device according to claim 1, wherein an uppermost position of a first wire connecting the first terminal to the first drain electrode is below an uppermost position of a second wire connecting the first source electrode to the second source electrode.

6. The semiconductor device according to claim 1, wherein the first groove portion is lined with a first joining material, and the first transistor is provided in the first groove portion on the first joining material.

7. The semiconductor device according to claim 1, wherein a distance from a bottom face of the first groove portion to an upper face of the second terminal in a thickness direction of the second terminal is smaller than a thickness of a portion of the substrate that is directly below the nitride semiconductor layer of the first transistor.

8. The semiconductor device according to claim 1, further comprising a second groove portion in the second terminal, wherein the second transistor is provided in the second groove portion via a second joining material.

9. The semiconductor device according to claim 1, wherein the first groove portion has a sidewall in thermal contact with a side surface of the first transistor.

10. A semiconductor device, comprising:
a first terminal;
a second terminal;
a first transistor that is a gallium-nitride transistor, mounted in a first groove formed through an upper surface of the second terminal, the first transistor having a first drain electrode electrically connected to the first terminal through a first bonding wire and a first source electrode; and
a second transistor mounted on the second terminal through a conductive bonding material, the second transistor having a second drain electrode electrically connected to the second terminal through the conductive bonding material and a second source electrode electrically connected to the first source electrode through a second bonding wire.

11. The semiconductor device according to claim 10, wherein the first transistor is a normally-on high electron mobility transistor (HEMT), and the second transistor is a normally-off metal-oxide-semiconductor field-effect transistor (MOSFET).

12. The semiconductor device according to claim 10, further comprising a first gate terminal, a second gate terminal, and a source control terminal, wherein the source control terminal is electrically connected to the first source electrode via a third bonding wire and to the second source electrode via a fourth bonding wire.

13. The semiconductor device according to claim 12, wherein the first gate terminal is electrically connected to a first gate electrode of the first transistor via a fifth bonding wire, and the second gate terminal is electrically connected to a second gate electrode of the second transistor via a sixth bonding wire.

14. The semiconductor device according to claim 10, wherein an uppermost position of the first bonding wire is below an uppermost position of the second bonding wire.

15. The semiconductor device according to claim 10, wherein the first groove portion is lined with a bonding material, and the first transistor is provided in the first groove portion on the bonding material.

16. The semiconductor device according to claim 10, wherein a distance from a bottom face of the first groove portion to an upper face of the second terminal in a thickness direction of the second terminal is smaller than a thickness of a portion of the substrate that is directly below the first transistor.

17. The semiconductor device according to claim 10, further comprising a second groove portion in the second terminal, wherein the second transistor is provided in the second groove portion via the conductive bonding material.

18. The semiconductor device according to claim 10, wherein the first groove portion has a sidewall in thermal contact with a side surface of the first transistor.

19. The semiconductor device according to claim 10, wherein the first source electrode and the first drain electrode are disposed on a nitride semiconductor layer of the first transistor.

20. The semiconductor device according to claim 19, wherein a semiconductor layer of the second transistor is between the second source electrode and the second drain electrode in a thickness direction of the second terminal.
